(19) United States
(12) Patent Application Publication
(10) Pub. No.: US 2025/0241083 A1
(43) Pub. Date: Jul. 24, 2025

(54) ELECTRONIC DEVICE

(71) Applicants: Innolux Corporation, Miaoli County (TW); InnoCare Optoelectronics Corporation, Tainan City (TW)

(72) Inventors: Yi-Chen Lee, Tainan City (TW); Chin-Chi Chen, Tainan City (TW); Kuan-Hsun Chen, Miaoli County (TW); Jie-Chen Shih, Miaoli County (TW)

(73) Assignees: Innolux Corporation, Miaoli County (TW); InnoCare Optoelectronics Corporation, Tainan City (TW)

(21) Appl. No.: 18/976,191

(22) Filed: Dec. 10, 2024

(30) Foreign Application Priority Data
Jan. 18, 2024 (TW) 113102080

(51) Int. Cl. H10F 39/00

(52) U.S. Cl. CPC H10F 39/811; H10F 39/802

(57) ABSTRACT

An electronic device including gate lines, data lines, switching elements, photosensitive elements and bias lines is provided. The data lines are electrically insulated and intersected with the gate lines. The switching elements are electrically connected to the gate lines and at least a part of the data lines. The photosensitive elements are electrically connected to at least a part of the switching elements. Each of the bias lines includes a first portion and a second portion. The first portion overlaps and is electrically insulated from a corresponding data line. The second portion is electrically connected to a corresponding photosensitive element. In a top view, the second portion extends from the first portion into an orthographic projection of the corresponding photosensitive element, and an overlapping area of the second portion and the corresponding photosensitive element is smaller than an area of the second portion.

### CROSS-REFERENCE TO RELATED APPLICATION

This application claims the priority benefit of Taiwan application serial no. 113102080, filed on Jan. 18, 2024. The entirety of the above-mentioned patent application is hereby incorporated by reference herein and made a part of this specification.

### BACKGROUND

### Technical Field

The disclosure relates to an electronic device.

### Description of Related Art

In order to meet the demand for high resolution, pixels in electronic devices are becoming smaller and smaller. Under the design of small-size pixels, a manufacturing process encounters a bottleneck of low yield. In this regard, there is a need for a circuit design capable of repairing defects to improve yield or reduce production costs.

### SUMMARY

The disclosure provides an electronic device, which has a circuit design capable of repairing defects.

An embodiment of the disclosure provides an electronic device including a plurality of gate lines, a plurality of data lines, a plurality of switching elements, a plurality of photosensitive elements and a plurality of bias lines. The plurality of data lines are electrically insulated and intersected with the plurality of gate lines. The plurality of switching elements are electrically connected to at least a part of the plurality of data lines and the plurality of gate lines. The plurality of photosensitive elements are electrically connected to at least a part of the plurality of switching elements. Each of the plurality of bias lines includes a first portion and a second portion. The first portion overlaps and is electrically insulated from a corresponding data line. The second portion is electrically connected to a corresponding photosensitive element. In a top view, the second portion extends from the first portion into an orthographic projection of the corresponding photosensitive element, and an overlapping area of the second portion and the corresponding photosensitive element is smaller than an area of the second portion.

Another embodiment of the disclosure provides an electronic device including a plurality of gate lines, a plurality of data lines, a plurality of switching elements and a plurality of photosensitive elements. The plurality of data lines are electrically insulated and intersected with the plurality of gate lines. The plurality of switching elements are electrically connected to at least a part of the plurality of data lines and the plurality of gate lines. The plurality of photosensitive elements are electrically connected to at least a part of the plurality of switching elements and overlap the plurality of gate lines. In a top view, a source electrode of each of the plurality of switching elements extends from a corresponding data line into an orthographic projection of a corresponding photosensitive element, and an overlapping area of the source electrode and the corresponding photosensitive element is smaller than an area of the source electrode.

In order for the aforementioned features and advantages of the disclosure to be more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic partial top view of an electronic device according to a first embodiment of the disclosure.

FIG. 2 and FIG. 3 are respectively schematic cross-sectional views corresponding to a section line I-I′ and a section line II-II′ in FIG. 1.

FIG. 4 to FIG. 6 are respectively schematic partial top views of an electronic device according to a second to fourth embodiments of the disclosure.

FIG. 7 is a schematic cross-sectional view corresponding to a section line III-III′ in FIG. 6.

FIG. 8 to FIG. 11 are respectively schematic partial top views of an electronic device according to a fifth to eighth embodiments of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Certain terms are used throughout the specification of the disclosure and the appended claims to refer to specific components. Those skilled in the art should understand that electronic device manufacturers may probably use different names to refer to the same components. This specification is not intended to distinguish between components that have the same function but different names. In the following specification and claims, the terms “including”, “containing”, etc., are open terms, so that they should be interpreted as meaning of “including but not limited to . . . ”.

Directional terminology mentioned in the specification, such as “top”, “bottom”, “front”, “back”, “left”, “right”, etc., is used with reference to the orientation of the figures being described. Therefore, the used directional terminology is only illustrative, and is not intended to be limiting of the disclosure. In the figures, the drawings illustrate general characteristics of methods, structures, and/or materials used in specific embodiments. However, these drawings should not be construed as defining or limiting of a scope or nature covered by these embodiments. For example, for clarity's sake, a relative size, a thickness and a location of each film layer, area and/or structure may be reduced or enlarged.

One structure (or layer, component, or substrate) described in the disclosure is located on/above another structure (or layer, component, or substrate), which may mean that the two structures are adjacent and in direct connection, or mean that the two structures are adjacent and in indirect connection. The indirect connection means that there is at least one intermediary structure (or intermediary layer, intermediary component, intermediary substrate, or intermediary spacer) between the two structures, a lower surface of one structure is adjacent to or directly connected to an upper surface of the intermediary structure, and an upper surface of another structure is adjacent to or directly connected to a lower surface of the intermediate structure. The intermediary structure may be composed of a single-layer or multi-layer physical structure or non-physical structure, which is not limited by the disclosure. In the disclosure, when a certain structure is disposed “on” another structure, it may mean that the certain structure is “directly” on the other structure, or that the certain structure is “indirectly” on the other structure, i.e., there is at least one structure sandwiched between the certain structure and the other structure.

The terms “about”, “substantially” or “approximately” are generally interpreted as being within a range of 10% of a given value or range, or as being within a range of 5%, 3%, 2%, 1%, or 0.5% of the given value or range. In addition, the terms “a range is a first value and a second value” and “a range is between the first value and the second value” mean that the range includes the first value, the second value and other values there between.

The ordinal numbers used in the specification and claims, such as “first”, “second”, etc., are used to modify components, and do not imply and represent the component or these components have any previous ordinal numbers, and do not represent a sequence of one component with another, or a sequence in a manufacturing method. The use of these ordinal numbers is only to make a clear distinction between a component with a certain name and another component with the same name. The same terms may not be used in the claims and the specification, and accordingly, a first component in the specification may be a second component in the claims.

In some embodiments of the disclosure, terms related to bonding and connecting, such as “connection”, “interconnection”, etc., unless otherwise defined, may mean that two structures are in direct contact, or may also mean that the two structures are not in direct contact, and other structures are located between the two structures. And the terms about bonding and connecting may also include the situation that both structures are movable, or both structures are fixed. In addition, the term “coupling” includes any direct and indirect electrical connection means. In addition, the term “link” includes a signal communication means between two elements or devices that may directly or indirectly receive and/or transmit wireless signals.

The electrical connection or coupling described in the disclosure may refer to direct connection or indirect connection. In the case of direct connection, terminals of components on the two circuits are directly connected or connected to each other by a conductor line segment, and in the case of indirect connection, there are switches, diodes, capacitors, inductors, resistors other suitable components, or a combination of the above components between the terminals of the components on the two circuits, but the disclosure is not limited thereto.

In the disclosure, thickness, length and width may be measured by using an optical microscope, and the thickness or width may be measured through a cross-sectional image in an electron microscope, but the disclosure is not limited thereto. In addition, any two values or directions used for comparison may have certain errors. In addition, the terms “a given range is a first value to a second value”, “the given range falls within the range of the first value to the second value” or “the given range is between a first value and a second value” means that the given range includes the first value, the second value and other values there between. If a first direction is perpendicular to a second direction, an angle between the first direction and the second direction may be between 80 degrees and 100 degrees; and if the first direction is parallel to the second direction, the angle between the first direction and the second direction may be between 0° and 10°.

It should be noted that, in the following embodiments, the features of several different embodiments may be replaced, reorganized, and mixed to complete other embodiments without departing from the spirit of the disclosure. As long as the features of the various embodiments do not violate the spirit of the disclosure or conflict with each other, they may be mixed and matched arbitrarily.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The types and patterns of electronic devices are not limited by the disclosure. For example, the electronic device may include a display device, a backlight device, an antenna device, a detection device, a splicing device or other types of devices. In addition, the electronic device may be a bendable or flexible electronic device. The display device may be a non-self-luminous display device or a self-luminous display device. The display device may include, for example, liquid crystal, light-emitting diode, fluorescence, phosphor, quantum dot (QD), other suitable display media, or a combination thereof. The antenna device may be a liquid crystal type antenna device or a non-liquid crystal type antenna device. The detection device may be a detection device that senses capacitance, light (such as visible light or X-rays), heat energy or ultrasonic waves, but the disclosure is not limited thereto. In some embodiments, the electronic device may include electronic components. The electronic components may include passive components and active components, such as capacitors, resistors, inductors, diodes, transistors, etc. Diodes may include light-emitting diodes or photodiodes. The light-emitting diodes may include, for example, organic light emitting diodes (OLEDs), mini LEDs, micro LEDs or quantum dot LEDs, but the disclosure is not limited thereto. The splicing device may be, for example, a display splicing device, a detection splicing device or an antenna splicing device, but the disclosure is not limited thereto.

It should be noted that the electronic device may be any permutation and combination of the above, but the disclosure is not limited thereto. In addition, a shape of the electronic device may be a rectangular shape, a circular shape, a polygonal shape, a shape with curved edges, or other suitable shapes. The electronic device may have a peripheral system such as a driving system, a control system, a light source system, etc., to support a display device, an antenna device, a wearable device (for example, including augmented reality or virtual reality), an in-vehicle device (for example, including a car windshield), or a splicing device, etc.

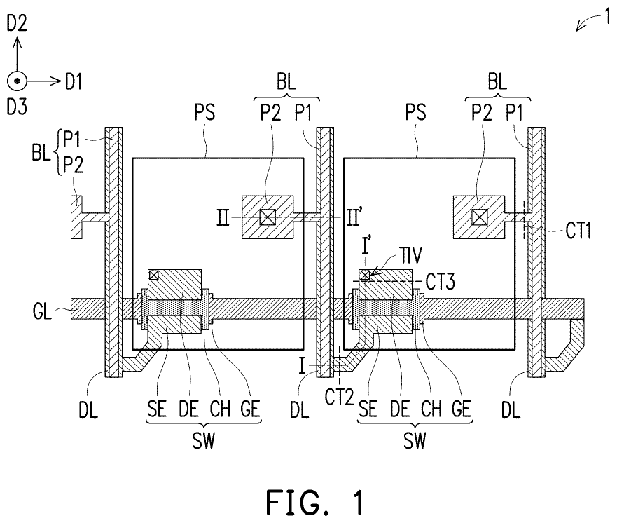

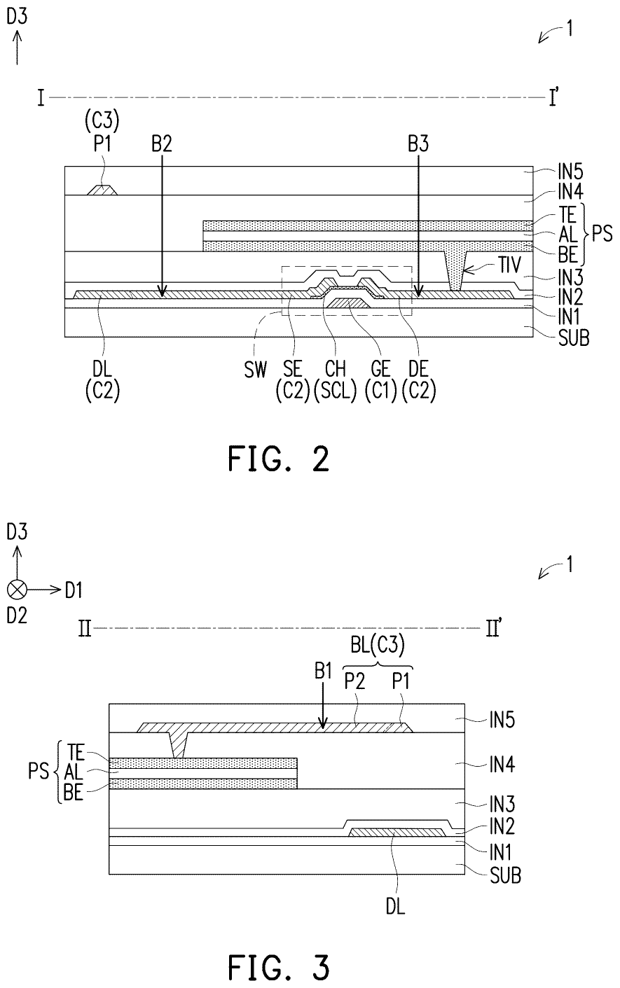

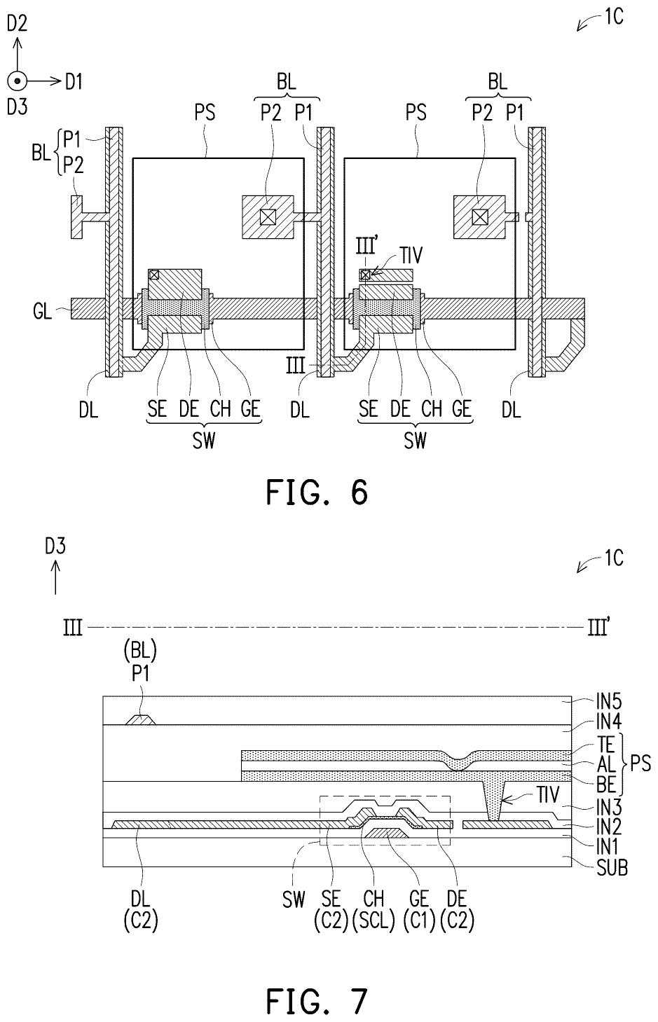

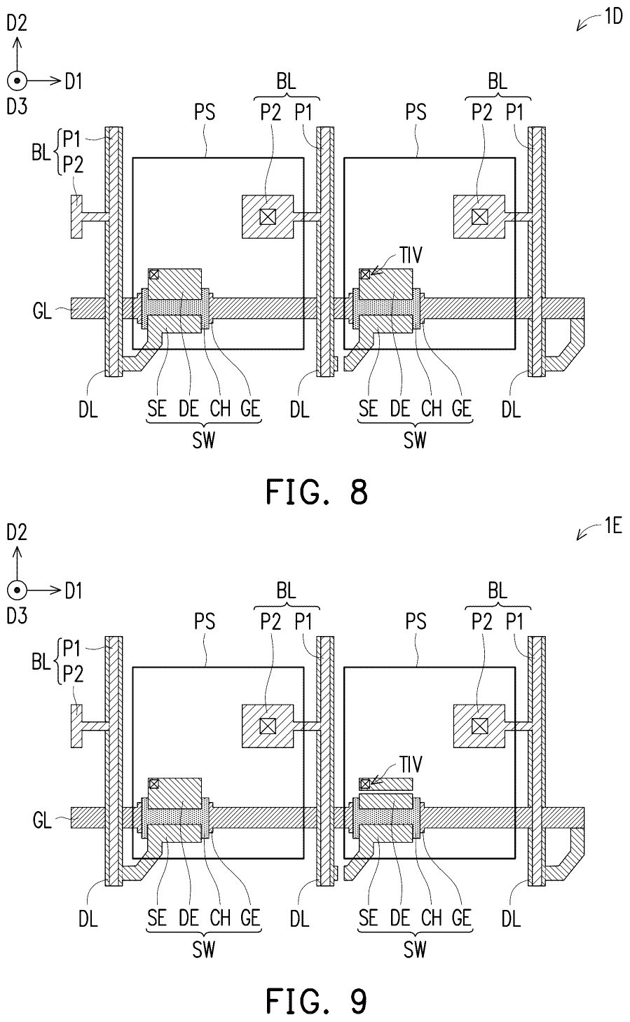

FIG. 1 is a schematic partial top view of an electronic device according to a first embodiment of the disclosure. FIG. 2 and FIG. 3 are respectively schematic cross-sectional views corresponding to a section line I-I′and a section line II-II′ in FIG. 1. FIG. 4 to FIG. 6 are respectively schematic partial top views of an electronic device according to a second to fourth embodiments of the disclosure. FIG. 7 is a schematic cross-sectional view corresponding to a section line III-III′ in FIG. 6. FIG. 8 to FIG. 11 are respectively schematic partial top views of an electronic device according to a fifth to eighth embodiments of the disclosure.

Referring to FIG. 1, an electronic device 1 may include a plurality of gate lines GL (only one is schematically shown), a plurality of data lines DL, a plurality of switching elements SW, a plurality of photosensitive elements PS and a plurality of bias lines BL. The plurality of data lines DL are electrically insulated and intersected with the plurality of gate lines GL. The plurality of switching elements SW are electrically connected to at least a part of the plurality of data lines DL and the plurality of gate lines GL. The plurality of photosensitive elements PS are electrically connected to at least a part of the plurality of switching elements SW. Each of the plurality of bias lines BL includes a first portion P1 and a second portion P2. The first portion P1 overlaps and is electrically insulated from a corresponding data line DL. The second portion P2 is electrically connected to a corresponding photosensitive element PS. In a top view (referring to FIG. 1), the second portion P2 extends from the first portion P1 into an orthographic projection (indicated by a thick solid line) of the corresponding photosensitive element PS, and an overlapping area of the second portion P2 and the corresponding photosensitive element PS is smaller than an area of the second portion P2.

In detail, the plurality of gate lines GL, for example, extends in a first direction D1 and are arranged in a second direction D2. The first direction D1 and the second direction D2 intersect each other and are both perpendicular to a thickness direction of the electronic device 1 (such as a third direction D3). In some embodiments, as shown in the figure, the first direction D1 and the second direction D2 may be perpendicular to each other.

The plurality of data lines DL, for example, extend in the second direction D2 and are arranged in the first direction D1. In some embodiments, the intersected plurality of gate lines GL and plurality of data lines DL may respectively belong to different conductive layers and may be electrically insulated from each other by one or more insulating layers/dielectric layers.

The plurality of switching elements SW are disposed adjacent to the intersections of the plurality of gate lines GL and the plurality of data lines DL and may be arranged in an array in the first direction D1 and the second direction D2. In some embodiments, each of the plurality of switching elements SW may include a gate electrode GE, a semiconductor pattern CH, a source electrode SE, and a drain electrode DE, but the disclosure is not limited thereto. The gate electrode GE may be electrically connected to a corresponding gate line GL. The semiconductor pattern CH overlaps the gate GE in the third direction D3. The source electrode SE and the drain electrode DE are respectively disposed at two opposite ends of the semiconductor pattern CH, where the source electrode SE may be electrically connected to a corresponding data line DL, and the drain electrode DE may be electrically connected to a corresponding photosensitive element PS. For example, the drain electrode DE may be electrically connected to a bottom electrode BE (referring to FIG. 2) of a corresponding photosensitive element PS.

A plurality of photosensitive elements PS are used to detect incident light. For example, as shown in FIG. 2, each of the plurality of photosensitive elements PS may include a bottom electrode BE, a top electrode TE, and a photosensitive structure AL disposed between the bottom electrode BE and the top electrode TE. In some embodiments, the photosensitive structure AL may include a stacked layer of a P-type semiconductor layer and an N-type semiconductor layer, or the photosensitive structure AL may include a stacked layer of a P-type semiconductor layer, an intrinsic semiconductor layer, and an N-type semiconductor layer, but the disclosure is not limited thereto.

In some embodiments, as shown in FIG. 1, the plurality of photosensitive elements PS may be respectively overlapped with the plurality of switching elements SW, and in the top view, the source electrode SE of each of the plurality of switching elements SW may extend from a corresponding data line DL into the orthographic projection of the corresponding photosensitive element PS, and an overlapping area of the source electrode SE and the corresponding photosensitive element PS may be smaller than an area of the source electrode SE. In other words, at least a part of the source electrode SE protrudes out from the corresponding photosensitive element PS, i.e., at least a part of the source electrode SE does not overlap the corresponding photosensitive element PS in the third direction D3.

By overlapping the photosensitive element PS and the switching element SW, an area of the photosensitive element PS may be increased, which helps to improve conversion efficiency. In a framework where the photosensitive element PS and the switching element SW are overlapped, if the source electrode SE is completely covered by the photosensitive element PS (i.e., the overlapping area of the source electrode SE and the photosensitive element PS is equal to the area of the source electrode SE), it may cause repair difficulties when it is required to repair the source electrode SE (such as laser repair). In the embodiment, by making at least a part of the source electrode SE to protrude out from the corresponding photosensitive element PS, when the source electrode SE needs to be repaired (for example, laser repair), the part of the source electrode SE that does not overlap the photosensitive element PS may be used as a repair location, which may reduce the difficulty of repair or improve a success rate of repair.

In some embodiments, under the framework where the photosensitive element PS and the switching element SW are overlapped, in the top view, as shown in FIG. 1, each of the plurality of switching elements SW may be located at a corner of the corresponding photosensitive element PS, which facilitate at least a part of the source electrode SE to protrude out from the corresponding photosensitive element PS and extend to the corresponding data line DL.

For example, the plurality of bias lines BL extend in the second direction D2 and are arranged in the first direction D1. In each of the plurality of bias lines BL, the first portion P1 overlaps and is electrically insulated from a corresponding data line DL. In some embodiments, the overlapped bias line BL and data line DL may respectively belong to different conductive layers and may be electrically insulated from each other by one or more insulating layers/dielectric layers. In each of the plurality of bias lines BL, the second portion P2 is electrically connected to a corresponding photosensitive element PS. For example, the second portion P2 is electrically connected to the top electrode TE of the corresponding photosensitive element PS (referring to FIG. 3).

The first portion P1 and the second portion P2 may be connected together for signal transmission. As shown in FIG. 1, the second portion P2 may extend from the first portion Pl into the orthographic projection of the corresponding photosensitive element PS, and an overlapping area of the second portion P2 and the corresponding photosensitive element PS is, for example, smaller than an area of the second portion P2. In other words, at least a part of the second portion P2 protrudes out from the corresponding photosensitive elements PS, i.e., at least a part of the second portion P2 does not overlap the corresponding photosensitive element PS in the third direction D3.

By making at least a part of the bias line BL (such as at least a part of the second portion P2) protruding out from the corresponding photosensitive element PS, when the bias line BL needs to be repaired (such as laser repair), the part of the second portion P2 that does not overlap the photosensitive element PS may be used as a repair location, which may reduce the difficulty of repair or improve a success rate of repair.

According to different requirements, the electronic device 1 may include other components or film layers. As shown in FIG. 2 and FIG. 3, the electronic device 1 may include a substrate SUB, a first conductive layer C1, a dielectric layer IN1, a semiconductor layer SCL, a second conductive layer C2, a dielectric layer IN2, a dielectric layer IN3, a dielectric layer IN4, a third conductive layer C3 and a dielectric layer IN5, but the disclosure is not limited thereto.

The substrate SUB may be a rigid substrate or a flexible substrate. A material of the substrate SUB includes, for example, glass, quartz, ceramics, sapphire or plastic, but the disclosure is not limited thereto. The plastic may include polycarbonate (PC), polyimide (PI), polypropylene (PP), polyethylene terephthalate (PET), and other suitable flexible materials or combinations of the aforementioned materials, but the disclosure is not limited thereto.

The first conductive layer C1 is disposed on the substrate SUB. A material of the first conductive layer C1 may include, for example, a transparent conductive material or an opaque conductive material. The transparent conductive material may include metal oxides, graphene, other suitable transparent conductive materials, or combinations thereof. The metal oxides may include indium tin oxide, indium zinc oxide, aluminum tin oxide, aluminum zinc oxide, indium germanium zinc oxide, or other metal oxides. The opaque conductive material may include metals, alloys, or combinations thereof. The metals may be a single layer of metal or a metal stack, such as aluminum, molybdenum or titanium/aluminum/titanium, but the disclosure is not limited thereto. The first conductive layer C1 may be a patterned conductive layer, and the first conductive layer C1 may include a plurality of gate electrodes GE, a plurality of gate lines GL (referring to FIG. 1) and other circuit lines (not shown), but the disclosure is not limited thereto.

The dielectric layer IN1 is disposed on the first conductive layer C1 and the substrate SUB. The dielectric layer IN1 may be a single layer or multi-layer. A material of the dielectric layer IN1 includes, for example, an organic insulating material, an inorganic insulating material or a combination thereof. The organic insulating material includes, for example, polymethylmethacrylate (PMMA), epoxy, acrylic-based resin, silicone, polyimide polymer, perfluoroalkoxy resin (PFA) or a combination thereof, but the disclosure is not limited thereto. The inorganic insulating material includes, for example, silicon oxide, silicon nitride or silicon oxynitride, but the disclosure is not limited thereto.

The semiconductor layer SCL is disposed on the dielectric layer IN1. A material of the semiconductor layer SCL includes, for example, amorphous silicon, polysilicon or metal oxide, such as indium gallium zinc oxide (IGZO), but the disclosure is not limited thereto. The semiconductor layer SCL may be a patterned semiconductor layer, and the semiconductor layer SCL may include a plurality of semiconductor patterns CH.

The second conductive layer C2 is disposed on the semiconductor layer SCL and the dielectric layer IN1. A material of the second conductive layer C2 may refer to the material of the first conductive layer C1, which will not be repeated here. The second conductive layer C2 may be a patterned conductive layer, and the second conductive layer C2 may include a plurality of source electrodes SE, a plurality of drain electrodes DE, a plurality of data lines DL and other circuit lines (not shown), but the disclosure is not limited thereto.

Although FIG. 2 schematically illustrates that the source electrode SE, the drain electrode DE and/or the data line DL are single-layer conductive layers, in other embodiments, although not shown, the source electrode SE, the drain electrode DE and/or the data line DL may include multi-layer conductive layers. For example, there may be another conductive layer (not shown) between the second conductive layer C2 and the bottom electrode BE, and a conductive pattern or wiring structure (not shown) in the other conductive layer that is used to electrically connect the drain electrode DE and the bottom electrode BE may be regarded as a part of the drain electrode DE. Similarly, the conductive pattern or wiring structure (not shown) in the other conductive layer that is electrically connected to the source electrode SE may be regarded as a part of the source electrode SE.

The dielectric layer IN2 is disposed on the second conductive layer C2, the semiconductor layer SCL and the dielectric layer IN1. The dielectric layer IN2 may be a single layer or multi-layer, and a material of the dielectric layer IN2 may refer to the material of the dielectric layer IN1, which will not be repeated here.

The dielectric layer IN3 is disposed on the dielectric layer IN2. The dielectric layer IN3 may be used to provide a flat surface carrying the plurality of photosensitive elements PS. A material of the dielectric layer IN3 includes, for example, an organic insulating material, but the disclosure is not limited thereto. Details of the organic insulating material may be referred to the above and will not be repeated here.

The plurality of photosensitive elements PS are disposed on the dielectric layer IN3, and the bottom electrode BE, the photosensitive structure AL and the top electrode TE of each of the plurality of photosensitive elements PS are, for example, stacked on the dielectric layer IN3 in sequence. The bottom electrode BE, for example, penetrates through the dielectric layer IN3 and the dielectric layer IN2 and is electrically connected to a corresponding drain electrode DE. A material of the bottom electrode BE may, for example, include a transparent conductive material or an opaque conductive material. A material of the top electrode TE may, for example, include a transparent conductive material, so that a light beam incident on the photosensitive element PS may penetrate through the top electrode TE and may be transmitted to the photosensitive structure AL.

The dielectric layer IN4 is disposed on the plurality of photosensitive elements PS and the dielectric layer IN3. A material of the dielectric layer IN4 may refer to the material of the dielectric layer IN1, which will not be repeated here.

The third conductive layer C3 is disposed on the dielectric layer IN4. A material of the third conductive layer C3 may refer to the material of the aforementioned first conductive layer C1 and will not be repeated here. The third conductive layer C3 may be a patterned conductive layer, and the third conductive layer C3 may include a plurality of bias lines BL and other lines (not shown), but the disclosure is not limited thereto. Each of the plurality of bias lines BL may penetrate through the dielectric layer IN4 and may be electrically connected to a corresponding top electrode TE.

The dielectric layer IN5 is disposed on the third conductive layer C3 and the dielectric layer IN4. A material of the dielectric layer IN5 may refer to the material of the dielectric layer IN1, which will not be repeated here.

A method of repairing the electronic device 1 may include cutting the second portion P2 with a laser beam B1 (referring to FIG. 3) and/or cutting the source electrode SE with a laser beam B2 (referring to FIG. 2). In some embodiments, the method of repairing the electronic device 1 may also include further cutting the drain electrode DE with a laser beam B3 (referring to FIG. 2), but the disclosure is not limited thereto. FIG. 1 schematically illustrates three cutting lines, where a cutting line CT1 falls on a part of the second portion P2 that does not overlap the photosensitive element PS, a cutting line CT2 falls on a part of the source electrode SE that does not overlap the photosensitive element PS, and a cutting line CT3 falls between a conductive via TIV of the drain electrode DE and the semiconductor pattern CH.

In some embodiments, the laser beam may cut the second portion P2 along the cutting line CT1 in FIG. 1, such that in at least one of the plurality of bias lines BL, the second portion P2 is disconnected at a position adjacent to the first portion P1. FIG. 4 illustrates an electronic device 1A after the above-mentioned laser repair. By repairing the part of the second portion P2 that does not overlap the photosensitive element PS instead of repairing the part of the second portion P2 that overlaps the photosensitive element PS or the first portion P1 that overlaps the data line DL, it may prevent the upper and lower conductive layers (such as the top electrode TE and the bottom electrode BE; the first portion P1 and the data line DL) from being short-circuited due to high-temperature melting during the laser cutting/repairing process, thereby maintaining normal operations of the components other than the repair.

In some embodiments, the laser beam may cut the source electrode SE along the cutting line CT2 in FIG. 1, so that in at least one of the plurality of switching elements SW, the source electrode SE is disconnected at a position adjacent to a corresponding data line DL. FIG. 8 illustrates an electronic device 1D after the above-mentioned laser repair. By repairing the part of the source electrode SE that does not overlap the photosensitive element PS instead of repairing the part of the source electrode SE that overlaps the photosensitive element PS, it may prevent the upper and lower conductive layers (such as the top electrode TE and the bottom electrode BE) from being short-circuited due to high-temperature melting during the laser cutting/repairing process, thereby maintaining normal operations of the components other than the repair.

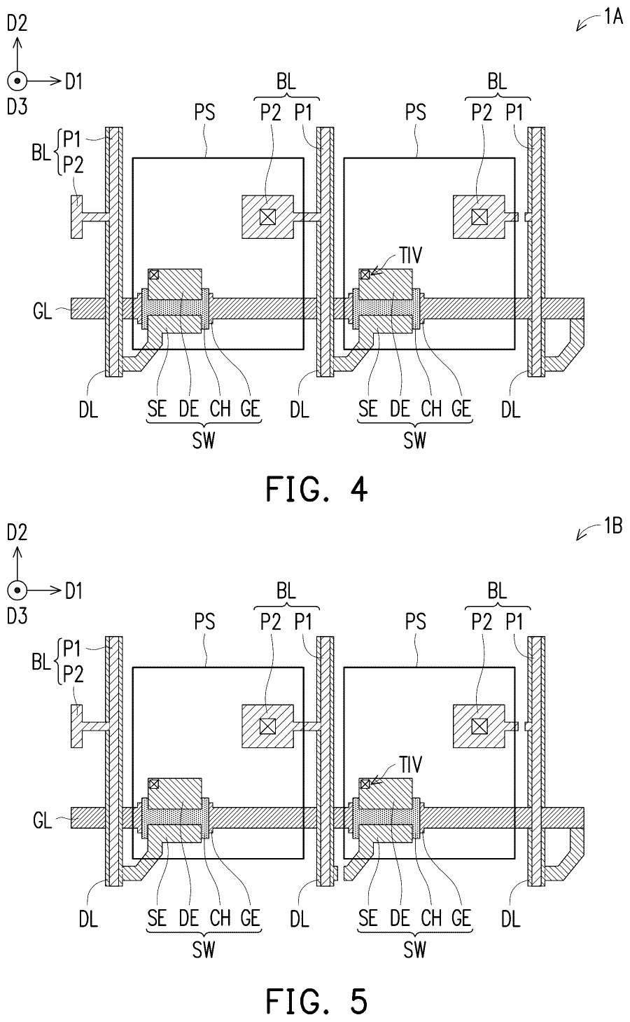

In some embodiments, the laser beam may cut along the cutting line CT1 and the cutting line CT2 in FIG. 1, so that in at least one of the plurality of bias lines BL, the second portion P2 is disconnected at a position adjacent to the first portion P1, and in one switching element SW corresponding to the at least one bias line BL, the source electrode SE is disconnected at a position adjacent to the corresponding data line DL. FIG. 5 illustrates an electronic device 1B after the above-mentioned laser repair.

In some embodiments, the laser beam may cut along the cutting line CT1 and the cutting line CT3 in FIG. 1, so that in at least one of the plurality of bias lines BL, the second portion P2 is disconnected at a position adjacent to the first portion P1, and in one photosensitive element PS corresponding to the at least one bias line BL, the top electrode TE and the bottom electrode BE of the corresponding photosensitive element PS are short-circuited to each other. FIG. 6 and FIG. 7 illustrate an electronic device 1C after the above-mentioned laser repair.

In some embodiments, the laser beam may cut along the cutting line CT2 and the cutting line CT3 in FIG. 1, so that in at least one of the plurality of switching elements SW, the source electrode SE is disconnected at a position adjacent to one corresponding data line DL, and in one photosensitive element PS corresponding to the at least one switching element SW, the top electrode TE and the bottom electrode BE of the corresponding photosensitive element PS are short-circuited to each other. FIG. 9 illustrates an electronic device 1E after the above-mentioned laser repair.

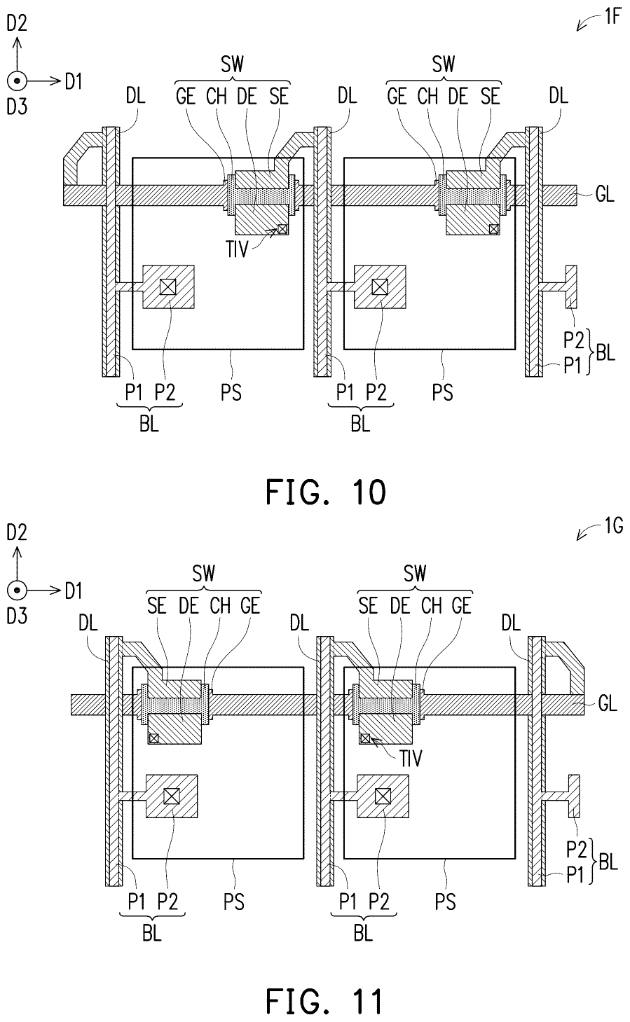

Although the above embodiments all show that the switching element SW is located at a lower left corner of the corresponding photosensitive element PS, the disclosure is not limited thereto. In other embodiments, the switching element SW may be located at an upper left corner, an upper right corner or a lower right corner of the corresponding photosensitive element PS. FIG. 10 schematically illustrates an electronic device IF in which the switching element SW is located at the upper right corner of the corresponding photosensitive element PS.

Although the above embodiments all show that the data line DL and the bias line BL used to control the same photosensitive element PS are respectively disposed on opposite sides (such as left and right sides) of the photosensitive element PS, the disclosure is not limited thereto. In other embodiments, the data line DL and the bias line BL used to control the same photosensitive element PS may be disposed on the same side of the photosensitive element PS, as shown in an electronic device 1G of FIG. 11.

In summary, in the embodiments of the disclosure, a design where at least a part of the bias line/source electrode does not overlap the photosensitive element may provide a convenient location for repair, which improves the success rate of repair.

The above embodiments are only used to illustrate the technical solutions of the disclosure rather than limit it; although the disclosure has been described in detail with reference to the foregoing embodiments, those with ordinary knowledge in the technical field should understand that they may still modify the technical solutions described in the foregoing embodiments, or make equivalent substitutions for some or all of the technical features; and these modifications or substitutions do not cause the essence of the corresponding technical solutions departing from the scope of the technical solutions of the embodiments of the disclosure.

Although the embodiments and advantages of the disclosure have been disclosed above, it should be understood that anyone with ordinary knowledge in the art may make changes and substitutions without departing from the spirit and scope of the disclosure, and the features of each embodiment may be arbitrarily mixed and replaced with each other to form other new embodiments. In addition, the protection scope of the disclosure is not limited to the processes, machines, manufacturing, material compositions, devices, methods and steps in the specific embodiments described in the specification. Anyone with ordinary skill in the art may understand the current or future developed processes, machines, manufacturing, material compositions, devices, methods, and steps from the disclosed content of the disclosure, as long as the same functionality or results may be achieved in the embodiments described here, they may be used according to the disclosure. Therefore, the protection scope of the disclosure includes the above-mentioned processes, machines, manufacturing, material compositions, devices, methods and steps. In addition, each claim constitutes an individual embodiment, and the protection scope of the disclosure also includes combinations of each claim and embodiment. The scope of protection of the disclosure shall be determined by the scope of the accompanying patent application.

What is claimed is:

1. An electronic device, comprising:
a plurality of gate lines;
a plurality of data lines electrically insulated and intersected with the plurality of gate lines;
a plurality of switching elements electrically connected to at least a part of the plurality of data lines and the plurality of gate lines;
a plurality of photosensitive elements electrically connected to at least a part of the plurality of switching elements; and
a plurality of bias lines, wherein each of the plurality of bias lines comprises:
a first portion overlapping and being electrically insulated from a corresponding data line; and
a second portion electrically connected to a corresponding photosensitive element, wherein in a top view, the second portion extends from the first portion into an orthographic projection of the corresponding photosensitive element, and an overlapping area of the second portion and the corresponding photosensitive element is smaller than an area of the second portion.

2. The electronic device according to claim 1, wherein in at least one of the plurality of bias lines, the second portion is disconnected at a position adjacent to the first portion.

3. The electronic device according to claim 2, wherein in the top view, a disconnection point of the second portion does not overlap the corresponding photosensitive element.

4. The electronic device according to claim 1, wherein the plurality of photosensitive elements respectively overlap the plurality of switching elements, and in the top view, a source electrode of each of the plurality of switching elements extends from the corresponding data line into the orthographicprojection of the corresponding photosensitive element, and an overlapping area of the source electrode and the corresponding photosensitive element is smaller than an area of the source electrode.

5. The electronic device according to claim 4, wherein in at least one of the plurality of bias lines, the second portion is disconnected at a position adjacent to the first portion, and in one switching element corresponding to the at least one bias line, the source electrode is disconnected at a position adjacent to the corresponding data line.

6. The electronic device according to claim 5, wherein in the top view, neither a disconnection point of the second portion nor a disconnection point of the source electrode overlaps the corresponding photosensitive element.

7. The electronic device according to claim 4, wherein in at least one of the plurality of bias lines, the second portion is disconnected at a position adjacent to the first portion, and in one photosensitive element corresponding to the at least one bias line, a top electrode and a bottom electrode of the corresponding photosensitive element are short-circuited to each other.

8. The electronic device according to claim 7, wherein in the top view, a disconnection point of the second portion does not overlap the corresponding photosensitive element, and a drain electrode that overlaps the corresponding photosensitive element is disconnected at a position where the top electrode and the bottom electrode are short-circuited.

9. The electronic device according to claim 1, wherein the plurality of photosensitive elements overlap the plurality of gate lines, and in the top view, each of the plurality of switching elements is located at a corner of the corresponding photosensitive element.

10. The electronic device according to claim 1, wherein a data line and a bias line for controlling a same photosensitive element are respectively disposed on opposite sides of the photosensitive element.

11. The electronic device according to claim 1, wherein a data line and a bias line for controlling a same photosensitive element are disposed on a same side of the photosensitive element.

12. An electronic device, comprising:
a plurality of gate lines;
a plurality of data lines electrically insulated and intersected with the plurality of gate lines;
a plurality of switching elements electrically connected to at least a part of the plurality of data lines and the plurality of gate lines; and
a plurality of photosensitive elements electrically connected to at least a part of the plurality of switching elements and overlap the plurality of gate lines, wherein in a top view, a source electrode of each of the plurality of switching elements extends from a corresponding data line into an orthographic projection of a corresponding photosensitive element, and an overlapping area of the source electrode and the corresponding photosensitive element is smaller than an area of the source electrode.

13. The electronic deviceaccording to claim 12, wherein in the top view, each of the plurality of switching elements is located at a corner of the corresponding photosensitive element.

14. The electronic device according to claim 12, wherein in at least one of the plurality of switching elements, the source electrode is disconnected at a position adjacent to the corresponding data line.

15. The electronic device according to claim 14, wherein in the top view, a disconnection point of the source electrode does not overlap the corresponding photosensitive element.

16. The electronic device according to claim 14, wherein in one photosensitive element corresponding to the at least one switching element, a top electrode and a bottom electrode of the corresponding photosensitive element are short-circuited to each other.

17. The electronic device according to claim 16, wherein in the top view, a drain electrode that overlaps the corresponding photosensitive element is disconnected at a position where the top electrode and the bottom electrode are short-circuited.

18. The electronic device according to claim 12, further comprising:
a plurality of bias lines, wherein a portion of each of the plurality of bias lines overlaps the corresponding data line.

19. The electronic device according to claim 18, wherein a data line and a bias line for controlling a same photosensitive element are respectively disposed on opposite sides of the photosensitive element.

20. The electronic device according to claim 18, wherein a data line and a bias line for controlling a same photosensitive element are disposed on a same side of the photosensitive element.
